(19) United States
(12) Patent Application Publication
(10) Pub. No.: US 2011/0157378 A1
(43) Pub. Date: Jun. 30, 2011

(54) Method for Providing A Hotkey Sequence Defined By A User and Photographic Device Using The Method

(76) Inventor: Hsiu-Hung Pien, Hsinchu City (TW)

(21) Appl. No.: 12/792,902

(22) Filed: Jun. 3, 2010

(30) Foreign Application Priority Data
Dec. 31, 2009 (TW) 098146585

(51) Int. Cl. H04N 5/225; H03M 11/00

(52) U.S. Cl. 348/207.99; 341/22; 348/E05.024

(57) ABSTRACT

A method for providing a hotkey sequence defined by a user and a photographic device using the method are disclosed. The method is used for the photographic device, and the photographic device comprises a plurality of keys. The method comprises the steps of: obtaining a using status of the photographic device; obtaining a first hotkey sequence inputted by the user; recording the first hotkey sequence; and making the first hotkey sequence correspond to the using status.

### BACKGROUND OF THE INVENTION

1. Field of the Invention

The present invention relates to a method for providing a hotkey sequence defined by a user and a photographic device; more particularly, the present invention relates to a method for providing a hotkey sequence defined by a user and a photographic device so that the user can set hotkeys of the photographic device.

2. Description of the Related Art

A hotkey is used for performing conveniently an operation with a specific key or a combination of keys. On a personal computer or a notebook computer, for example, a Ctrl key, a Shift key, an Alt key or a Fn key is often used with another key to perform an operation or launch a program. In the Microsoft operating system, “Ctrl+C” is used for copying, and “Shift+a number key” is used for displaying a symbol corresponding to the number key depressed. The hotkey can also directly correspond to a software program; for example, some hotkeys on a keyboard or a mouse correspond individually to programs within the operating system. However, these hotkeys are preset by software or hardware and cannot be changed by the user. In prior arts, although some programs provide for the user to set hotkeys as the user wishes, few functions are provided, and the user cannot set the function to correspond to any using status; the current system lacks flexibility and convenience.

On a photographic device (such as a digital camera or a digital video camera), function keys are preset, and the user cannot change them; hence, there is a lack of flexibility and convenience for the user.

Therefore, there is a need to provide a method for providing a hotkey sequence defined by a user and a photographic device to mitigate and/or obviate the aforementioned problems.

### SUMMARY OF THE INVENTION

It is an object of the present invention to provide a method for providing a hotkey sequence defined by a user and a photographic device so that the user can set hotkeys of the photographic device.

To achieve the abovementioned object, the method for providing the hotkey sequence defined by the user of the present invention is used for a photographic device, wherein the photographic device comprises a plurality of keys, the method comprising the steps of: obtaining a using status of the photographic device; obtaining a first hotkey sequence inputted by the user; recording the first hotkey sequence; and making the first hotkey sequence correspond to the using status.

In one embodiment of the present invention, the first hotkey sequence comprises a corresponding functional key and a trigger functional key; wherein the corresponding functional key is used for corresponding to the using status and the trigger functional key is used for recording or triggering the corresponding functional key.

To achieve the abovementioned object, the photographic device of the present invention comprises a photographic module, a display module, a plurality of keys, a status detecting module, a storage device, and a hotkey controlling module, wherein the photographic module is used for capturing an image; the display module is used for displaying the image or a menu; the plurality of keys is used for a first hotkey sequence inputted by a user; the status detecting module is used for detecting a using status of the photographic device; the storage device is used for storing the first hotkey sequence; and the hotkey controlling module is electrically connected with the photographic module, display module, the plurality of keys, the status detecting module, and the storage device. When the first hotkey sequence is inputted, the hotkey controlling module makes the first hotkey sequence correspond to the using status and stores the first hotkey sequence in the storage device.

In one embodiment of the present invention, the first hotkey sequence comprises a corresponding functional key and a trigger functional key, wherein the corresponding functional key is used for corresponding to the using status and the trigger functional key is used for recording or triggering the corresponding functional key.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 illustrates a hardware architecture of a photographic device according to one embodiment of the present invention.

FIG. 2 illustrates a schematic drawing of a photographic device according to one embodiment of the present invention.

FIGS. 3˜7 are flowcharts of a method for providing a hotkey sequence defined by a user according to one embodiment of the present invention

### DETAILED DESCRIPTION OF THE PREFERRED EMBODIMENT

The following detailed description will present a preferred embodiment of the invention in reference to the accompanying drawings, in which well-known functions or constructions will not be described in detail since they would unnecessarily obscure the understanding of the invention.

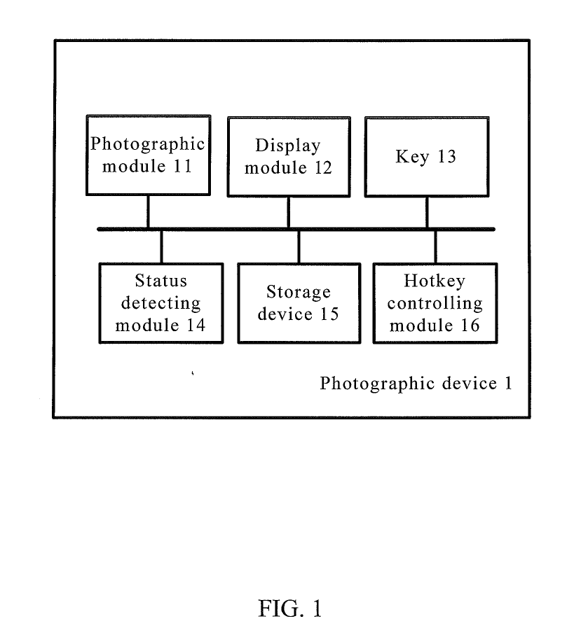

Please refer to FIG. 1 of a photographic device according to one embodiment of the present invention. FIG. 1 illustrates a hardware structure of the photographic device according to one embodiment of the present invention.

As shown in FIG. 1, the photographic device 1 of the present invention comprises a photographic module 11, a display module 12, a plurality of keys 14, a status detecting module 14, a storage device 15, and a hotkey controlling module 16, and these devices and modules abovementioned are electrically connected with each other.

In one embodiment of the present invention, the photographic module 11 is used for capturing an image, wherein the image is, but is not limited to, a picture or a video. The display module 12 is used for displaying the image or a menu. The plurality of keys 13 is provided for a user to operate the photographic device 1 and used for a first hotkey sequence or a second hotkey sequence inputted by the user. The status detecting module 14 is used for detecting a using status. The storage device 15 is used for storing the first hotkey sequence, wherein the first hotkey sequence corresponds to the using status. The hotkey controlling module 16 is used for making the first hotkey sequence correspond to the using status, and storing the first hotkey sequence in the storage device 15; when the second hotkey sequence is inputted by the user, the hotkey controlling module 16 is used for canceling the first hotkey sequence corresponding to the using status.

In one embodiment of the present invention, the device or the module can be not only hardware, software, firmware, or a combination of these elements, but also a circuit or other proper type; and each module can be set in a single type or a combinative type with each other.

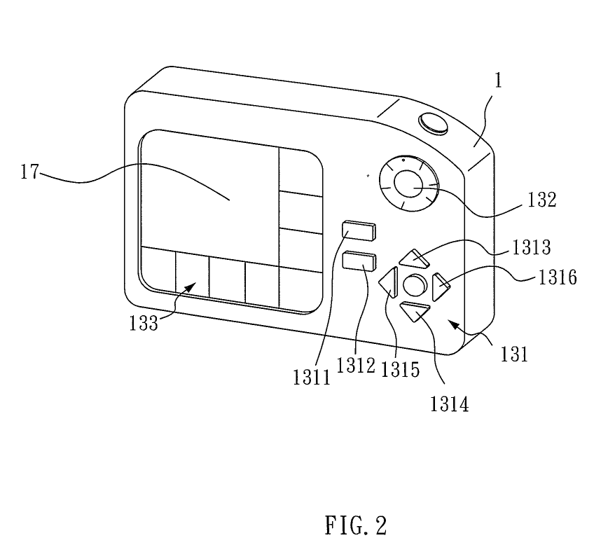

As shown in FIG. 2, the photographic device 1 of the present invention is, but is not limited to, a digital camera. For example, the photographic device 1 of the present invention can also be a digital video camera, a personal digital assistant capable of capturing photos, or another photographic device capable of capturing photos.

The method for providing the hotkey sequence defined by the user performed by the photographic device 1 of the present invention as shown in FIG. 1 and FIG. 2 will be described hereinafter. Please note that the method of the invention is not limited to the photographic device 1 of the present invention as shown in FIG. 1 and FIG. 2.

Please refer to FIGS. 1˜3, which is one embodiment of the method for providing the hotkey sequence defined by the user of the present invention.

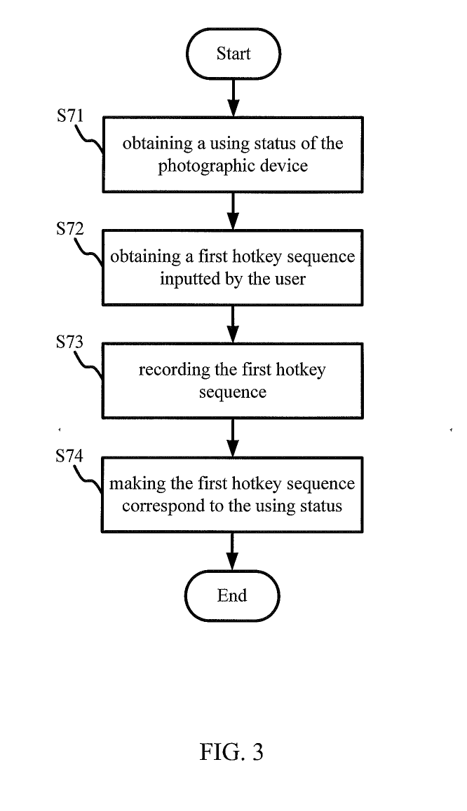

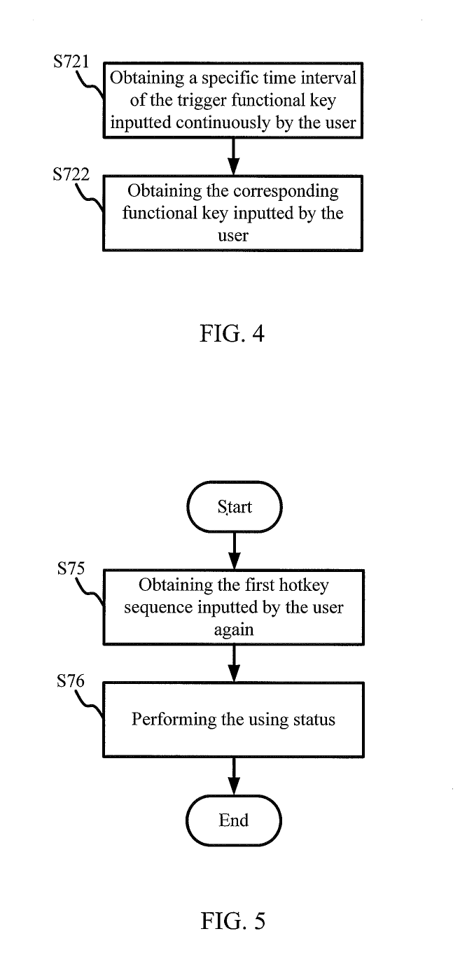

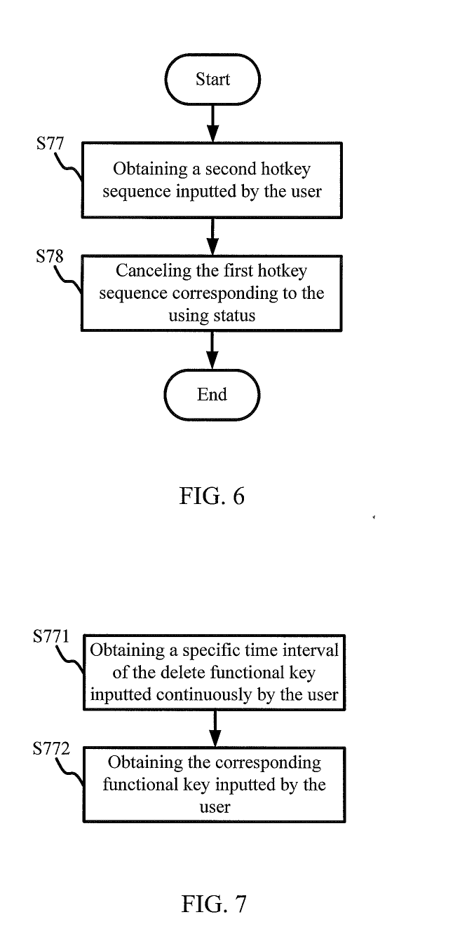

As shown in FIG. 3, the present invention first performs step S71: obtaining a using status of the photographic device.

In one embodiment of the present invention, the status detecting module 14 is used for detecting a using status of the photographic device 1. When the user starts to use the photographic device 1, the user begins to perform operations of the photographic device 1; in one embodiment of the present invention, the using status of the photographic device 1 comprises, but is not limited to, a photo capturing status, a video capturing status, a browsing status, or a menu status. In one embodiment of the present invention, when the user adjusts parameters of the photographic device 1, the using status comprises, but is not limited to, a photo capturing parameter, a video capturing parameter, or a menu parameter. In one embodiment of the present invention, when the user previews photos or videos, the using status comprises, but is not limited to, a browsing a specific photo status or a browsing a specific segment of a video status.

Then the present invention performs step S72: obtaining a first hotkey sequence inputted by the user.

When the user is operating the photographic device 1 in a specific using status, if the user wants to make a hotkey sequence in correspondence with that using status, whereby the user can change the status of the photographic device to the abovementioned using status quickly with a hotkey sequence entered in any other using status, then the user uses the plurality of keys 13 to generate an input of a first hotkey sequence which corresponds to the using status.

As shown in FIG. 2, in one embodiment of the present invention, the plurality of keys 13 comprises, but is not limited to, at least one entity key 131, at least one functional rotary plate 132 or at least one virtual key 133 of a touch screen. In one embodiment of the present invention, the first hotkey sequence comprises a corresponding functional key and a trigger functional key; wherein the corresponding functional key is used for corresponding to the using status and the trigger functional key is used for recording or triggering the corresponding functional key. In one embodiment of the present invention, the corresponding functional key or the trigger functional key can be, but is not limited to, the entity key 131, the functional rotary plate 132, the virtual key 133 of the touch screen, or a combination of these elements. Therefore, the corresponding functional key or the trigger functional key of the present invention need not occupied any space on an appearance of the photographic device 1.

As shown in FIG. 4, in one embodiment of the present invention, the step S72 further comprises steps S721 and S722.

Step S721: obtaining a specific time interval of the trigger functional key inputted continuously by the user.

Step S722: obtaining the corresponding functional key inputted by the user.

In one embodiment of the present invention, the specific time interval is substantially between 1 second and 3 seconds. However, please note that the scope of the present invention is not limited to the above description. The specific time interval prevents unintentional setting of a correspondence due to continual pressure applied accidentally to the corresponding functional key and trigger functional key.

Then the present invention performs step S73: recording the first hotkey sequence.

Then the present invention performs step S74: making the first hotkey sequence correspond to the using status.

In one embodiment of the present invention, when the user presses the corresponding functional key and trigger functional key, the hotkey controlling module 16 makes the first hotkey sequence correspond to the using status and stores the first hotkey sequence in the storage device 15.

In one embodiment of the present invention, after the user operates the photographic device 1 in another using status, if the user wants to return to the using status corresponding to the first hotkey sequence, as shown in FIG. 5, the present invention performs step S75: obtaining the first hotkey sequence inputted by the user again. Then the present invention performs step S76: performing the using status, whereby the photographic device 1 can return to the using status corresponding to the first hotkey sequence quickly.

In one embodiment of the present invention, when the user wants to cancel the first hotkey sequence corresponding to the using status, as shown in FIG. 6, the present invention performs step S77: obtaining a second hotkey sequence inputted by the user.

In one embodiment of the present invention, the second hotkey sequence comprises the corresponding functional key and a delete functional key, wherein the delete functional key is used for canceling the corresponding functional key corresponding to the using status. In one embodiment of the present invention, the delete functional key can be, but is not limited to, the entity key 131, the functional rotary plate 132, or the virtual key 133 of the touch screen.

Then the present invention performs step S78: canceling the first hotkey sequence corresponding to the using status.

In one embodiment of the present invention, step S77 further comprises steps S771 and step S772.

Step S771: obtaining a specific time interval of the delete functional key inputted continuously by the user.

Step S772: obtaining the corresponding functional key inputted by the user.

In one embodiment of the present invention, the specific time interval is substantially between 1 second and 3 seconds. However, please note that the scope of the present invention is not limited to the above description. The specific time interval prevents unintentional setting of a correspondence due to continual pressure applied accidentally to the corresponding functional key and trigger functional key.

One embodiment of the method for providing the hotkey sequence defined by the user and the photographic device of the present invention will be described hereinafter.

As shown in FIG. 2, the entity key 131 comprises a menu key 1311, a delete key 1312, an up key 1313, a down key 1314, a left key 1315, and a right key 1316. In one embodiment of the present invention, the trigger functional key is the menu key 1311, the delete functional key is the delete key 1312, and the corresponding functional key comprises the up key 1313, the down key 1314, the left key 1315, or the right key 1316; in one embodiment of the present invention, the corresponding functional key can also be another entity key or a virtual key of the photographic device 1.

In one embodiment of the present invention, the user uses the photographic device 1 in the photo capturing status for capturing a remote object, and in order to get a better capturing effect, the user adjusts the photo capturing parameters of optical focus distance, ISO value, and aperture value; since the user may use the photographic device 1 in other using statuses or capture photos at different distances, the user may change the using status at any time. In order to keep the using status of the remote object in the abovementioned distance and avoid having to set it again later, the user can press the menu key 1311 and the up key 1313 to generate a hotkey sequence; the menu key 1311 and the up key 1313 will correspond to the using status of the remote object in the longer distance. In the subsequent operation, no matter what the status of the photographic device 1 is, if the user wants to return to the using status of the remote object in the longer distance, the user just presses the menu key 1311 and the up key 1313. If the user wants to cancel the combination of the menu key 1311 and the up key 1313 corresponding to the using status, the user needs only to press the delete key 1312 and the up key 1313.

In one embodiment of the present invention, the user has captured hundreds of photos stored in the storage device 15. In browsing status, the user wants to view a specific photo; however, if the user leaves the browsing status and later enters the browsing status again, the user needs to spend a lot of time to find the specific photo. In one embodiment of the present invention, when the user previews the specific photo, the user presses the menu key 1311 and the down key 1314 to set a hotkey sequence; the menu key 1311 and the down key 1314 will correspond to viewing the specific photo. In the subsequent operation, no matter what the status of the photographic device 1 is, if the user wants to preview the specific photo, the user just presses the menu key 1311 and the down key 1314. If the user wants to cancel the correspondence of the menu key 1311 and the down key 1314 to viewing the specific photo, the user needs only to press the delete key 1312 and the down key 1314.

Although the present invention has been explained in relation to its preferred embodiments, it is to be understood that many other possible modifications and variations can be made without departing from the spirit and scope of the invention as hereinafter claimed.

What is claimed is:

1. A method for providing a hotkey sequence defined by a user, used for a photographic device, wherein the photographic device comprises a plurality of keys, the method comprising the steps of:
obtaining a using status of the photographic device;
obtaining a first hotkey sequence inputted by the user, wherein the first hotkey sequence comprises at least two keys of the photographic device;
recording the first hotkey sequence; and
making the first hotkey sequence correspond to the using status.

2. The method as claimed in claim 1, wherein the first hotkey sequence comprises:
a corresponding functional key, used for corresponding to the using status; and
a trigger functional key, used for recording or triggering the responding functional key.

3. The method as claimed in claim 2, wherein the step of obtaining the first hotkey sequence inputted by the user further comprises the steps of:
obtaining a specific time interval of the trigger functional key inputted continuously by the user; and
obtaining the corresponding functional key inputted by the user.

4. The method as claimed in claim 1, wherein the using status comprises a photo capturing status, a video capturing status, a browsing status, or a menu status.

5. The method as claimed in claim 1, wherein the using status comprises a photo capturing parameter, a video capturing parameter, or a menu parameter.

6. The method as claimed in claim 1, wherein the using status comprises a browsing a specific photo status or a browsing a specific segment of a video status.

7. The method as claimed in claim 1, wherein the method further comprises the steps of:
obtaining the first hotkey sequence inputted by the user again; and
performing the using status.

8. The method as claimed in claim 1, further comprising the steps of:
obtaining a second hotkey sequence inputted by the user; and
canceling the first hotkey sequence corresponding to the using status.

9. The method as claimed in claim 8, wherein the second hotkey sequence comprises:
the corresponding functional key; and
a delete functional key, used for canceling the correspondence of the functional key to the using status.

10. The method as claimed in claim 9, wherein the step of obtaining the second hotkey sequence inputted by the user further comprises the steps of:
obtaining a specific time interval of the delete functional key inputted continuously by the user; and
obtaining the corresponding functional key inputted by the user.

11. The method as claimed in claim 1, wherein the plurality of keys comprises at least one entity key, at least one functional rotary plate or at least one virtual key of a touch screen.

12. The method as claimed in claim 9, wherein the plurality of keys comprises a menu key, a delete key, an up key, a down key, a left key, and a right key; wherein the trigger functional key is the menu key, the delete functional key is the delete key, and the corresponding functional key comprises the up key, the down key, the left key, or the right key.

13. A photographic device, comprising:
a photographic module, used for capturing an image;
a display module, used for displaying the image or a menu;
a plurality of keys, used for a first hotkey sequence inputted by a user;
a status detecting module, used for detecting a using status of the photographic device;
a storage device, used for storing the first hotkey sequence, wherein the first hotkey sequence corresponds to the using status; and
a hotkey controlling module, electrically connected with the photographic module, the display module, the plurality of keys, the status detecting module, and the storage device; when the first hotkey sequence is inputted, the hotkey controlling module makes the first hotkey sequence correspond to the using status and stores the first hotkey sequence in the storage device.

14. The photographic device as claimed in claim 13, wherein the first hotkey sequence comprises:
a corresponding functional key, used for corresponding to the using status; and
a trigger functional key, used for recording or triggering the corresponding functional key;

15. The photographic device as claimed in claim 13, wherein the using status comprises a photo capturing status, a video capturing status, a browsing status, a menu status, a browsing a specific photo status or a browsing a specific segment of a video status.

16. The photographic device as claimed in claim 13, wherein the using status comprises a photo capturing parameter, a video capturing parameter, or a menu parameter.

17. The photographic device as claimed in claim 13, wherein when the hotkey controlling module detects that the first hotkey sequence is inputted again, the hotkey controlling module performs the using status.

18. The photographic device as claimed in claim 17, wherein the plurality of keys is used for a second hotkey sequence inputted by the user, the second hotkey sequence comprising a delete functional key and the corresponding functional key; whereby, after the second hotkey sequence is inputted, the hotkey controlling module is used for canceling the correspondence of the functional key to the using status.

19. The photographic device as claimed in claim 13, wherein the plurality of keys comprises at least one entity key, a functional rotary plate, or at least one virtual key of a touch screen.

20. The photographic device as claimed in claim 18, wherein the plurality of keys comprises a menu key, a delete key, an up key, a down key, a left key, and a right key; wherein the trigger functional key is the menu key, the delete functional key is the delete key, and the corresponding functional key comprises the up key, the down key, the left key, or the right key.
